(19) United States
(12) Patent Application Publication
(10) Pub. No.: US 2006/0046464 A1
(43) Pub. Date: Mar. 2, 2006

(54) Wiring substrate and semiconductor device using the same

(76) Inventors: Masayuki Miura, Tokyo (JP); Katsuto Kato, Yokohama-shi (JP); Hiroshi Ikebe, Oita-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/211,712

(22) Filed: Aug. 26, 2005

(30) Foreign Application Priority Data
Aug. 31, 2004 (JP) P2004-251976

(51) Int. Cl. H01L 21/4763

(52) U.S. Cl. 438/622

(57) ABSTRACT

A wiring substrate provides an inner wiring substrate having through hole portions. On at least one main surface of the inner wiring substrate, a plurality of build up layers are laminated. The build up layers have a stacked via, for example, as a power source system via. The stacked via is formed by stacking the vias in multiple steps to form a straight line. The stacked via has a large diameter via which is larger than other via constituting the stacked via, or is constituted of large diameter vias larger than other via in the same build up layer.

### CROSS-REFERENCE TO RELATED APPLICATIONS

This application is based upon and claims the benefit of the priority from the prior Japanese Patent Application No. 2004-251976 filed on Aug. 31, 2004: the entire contents of which are incorporated herein by reference.

### BACKGROUND

1. Field of the Invention

This invention relates to a wiring substrate which can be applied as a package substrate of a semiconductor element and the like, and a semiconductor device using the same.

2. Description of the Related Art

Recently, in a package substrate of a semiconductor device, it is required to provide a wiring having higher density. To satisfy such requirement, a multi-layered wiring substrate (build-up substrate) is widely used. The multi-layered wiring substrate has a build-up structure in which insulating layers and wiring layers are laminated alternatively on both surfaces or one surface of an inner wiring substrate (core substrate). As a connection between the build-up layers, a via is used. In order to cope with the miniaturization and high integration of the semiconductor element, the diameter of signal system via has a tendency to be finer.

That is, when the line numbers of the bump in a signal wiring region surrounding the semiconductor element increases, in order to prevent a cost up accompanying the increase of the layer numbers, it becomes necessary to wire between the signal bumps (at a side of package, between lands). For this reason, it is required to be finer the signal wiring, and simultaneously, to be finer the diameter of via. Especially, accompanying with increasing of line numbers of the signal bumps, since the numbers of signals which pass through between the signal bumps increase (at a package substrate side, between the lands), the diameter of signal system vias has a tendency to be more fine (to be miniaturized).

On the other hand, in a power source system via, it is required to decrease the inductance thereof. Then, the application of a stacked via structure is considered. (For example, refer to Japanese Patent Laid-open Application No. 2003-264253). The stacked via is a lamination in which multiple vias are stacked to form a straight line in multiple steps, the wiring distance can be decreased. The stacked via is effective to decrease the inductance thereof. In contrast, when the respective positions of vias are shifted little by little in the same way as a usual signal series via, excessive wirings corresponding to moving distance are necessary. Therefore, an increase of inductance can not be avoided. As mentioned above, the stacked via is effective to the electric power system via and the application thereof is proceeded.

A via diameter in a build up substrate generally has the same diameter in respective layers. This is because in a forming process of the build up layers, a condition for processing the via in an insulating layer by a laser processing or the like is required to be unified. Therefore, the via diameter in respective layers of the build up substrate is set to be the same. Concrete via diameter depends on a signal system via diameter. Thus, also in a power source system via applying the stacked via structure, the via diameter is to be finer as the signal system via becomes finer.

As described above, in the build up substrate which is used as a package substrate of semiconductor element, a stacked via is effective as a power source system via, but there is a tendency that vias constituting the stacked via are also to be finer as the signal system via becomes to be finer. The stacked via is easily subjected to the stress concentration compared with usual vias (vias which are disposed by shifting its position). As the result, due to a thermal stress occurred when mounting a semiconductor element on a package substrate and a thermal stress based on the operating temperature of the semiconductor element, a stacked via which was miniaturized has a tendency to be easily broken. Particularly, when a stacked via is applied to the power source system via, the break down is easily produced.

### SUMMARY

A wiring substrate according to one embodiment of the present invention comprises an inner wiring substrate having through hole portions, and a plurality of build up layers formed by laminating on at least one main surface of the inner wiring substrate and each having vias electrically connected to the through hole portions, wherein the plurality of build up layers have a stacked via which is formed by stacking the vias in multiple steps to form a straight line, and the stacked via has a large diameter via whose diameter is larger than other via forming the stacked via.

A wiring substrate according to another embodiment of the present invention comprises an inner wiring substrate having through hole portions, and a plurality of build up layers formed by laminating on at least one main surface of the inner wiring substrate and each having vias electrically connected to the through hole portions, wherein the plurality of build up layers have a stacked via which is formed by stacking the vias in multiple steps to form a straight line, and the stacked via is constituted with large diameter vias, the large diameter via having a diameter larger than other via in the same build up layer.

A semiconductor device according to an embodiment of the present invention has the above-mentioned wiring substrate according to the embodiments of the present invention, and a semiconductor element mounted on the build up layers of wiring substrate and electrically connected to the via.

### BRIEF DESCRIPTION OF THE DRAWINGS

The present invention will be described with reference to the drawings. The drawings are used only for illustrating, and do not limit the invention.

FIG. 1 is a sectional view showing a structure of the wiring substrate according to a first embodiment of the present invention.

FIG. 2 is an enlarged sectional view showing an essential structure of the wiring substrate shown in FIG. 1.

FIG. 3 is an enlarged sectional view showing an essential structure of a wiring substrate according to a second embodiment of the present invention.

FIG. 4 is a sectional view showing a structure of a semiconductor device according to an embodiment of the present invention.

### DETAILED DESCRIPTION

Embodiments of the present invention will be described with reference to the accompanying drawings. The following description of the embodiments of the invention is made based on the drawings, but the invention is not limited to the drawings, because the drawing is provided to explain by illustrating.

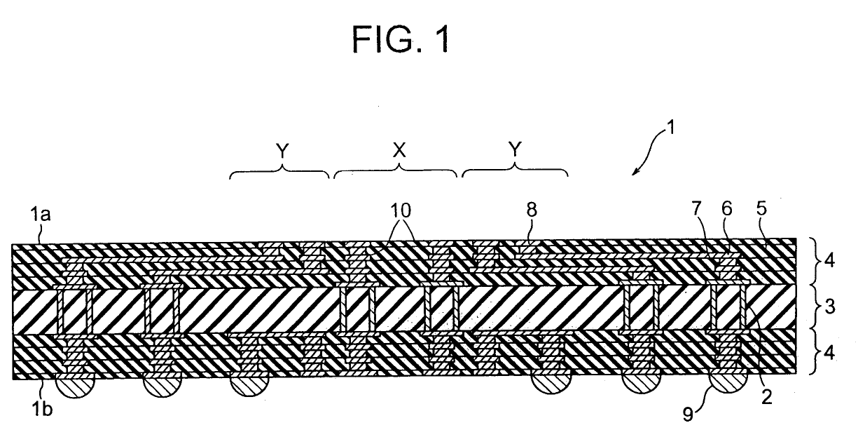

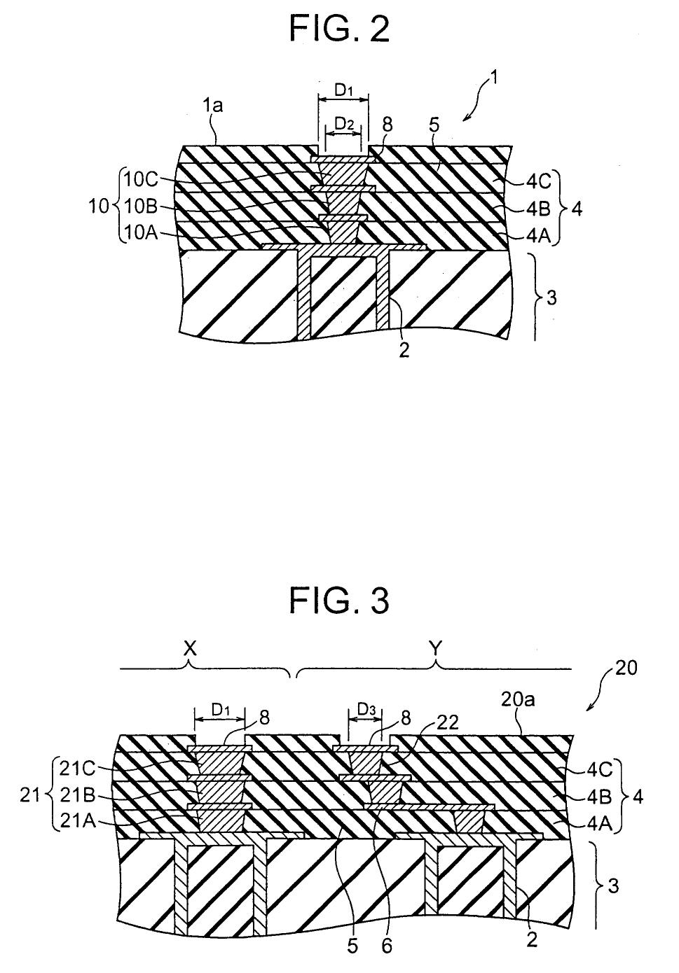

FIG. 1 is a sectional view showing a structure of a wiring substrate according to a first embodiment of the invention, and FIG. 2 is an enlarged sectional view showing an essential part thereof. A wiring substrate 1 shown in these figures provides an inner wiring substrate 3 having through hole portions (through hole conductive portions) 2 where a conductive layer is formed in a through hole. As the inner wiring layer 3, a glass-epoxy resin substrate, bis-maleinimide-triazine (BT) resin substrate, a polyimide resin substrate, a fluororesin type substrate and the like are used.

The resin substrate which constitutes the inner wiring substrate 3 has through holes. On a surface of the resin substrate comprising an inner surface of the through hole, a copper plating is performed, thereby a predetermined conductive pattern (wiring layer) is formed. Thus, the inner wiring substrate 3 having the through hole portion 2 is constituted. Here, the inner wiring substrate 3 may have a multiple layered wiring structure. Such inner wiring substrate 3 functions as a core substrate and on both main surfaces thereof a plurality of build-up layers 4 are laminated, respectively.

FIGS. 1 and 2 show a three-layer laminated structure which is formed by laminating three build-up layers 4 on respective main surfaces of the inner wiring substrate 3. Namely, on one side of main surfaces (element mounting surface side) of the inner wiring substrate 3, as shown in FIG. 2, a first build-up layer 4A, a second build-up layer 4B, and a third build-up layer 4C are laminated. On another side of main surfaces of the inner wiring substrate 3, a similar structure is formed. Here, the laminate numbers of build-up layers are not limited to the above. The numbers can be properly set depending on the numbers of signal wiring numbers, the wiring pattern and the like. The build-up layers 4 may be formed on either one side of the main surfaces of the inner wiring substrate 3.

Each of the plurality of build-up layers 4 has an insulating layer 5 and a wiring layer (conductive layer) 6. The insulating layer 5 and the wiring layer 6 are laminated in turn, and simultaneously by electrical connecting between wiring layers 6 with via 7, the multilayer structure comprising the plurality of build-up layers 4 is formed. For forming the build-up layer 4, for example, a semi-additive method or a full-additive method can be applied.

For example, in case of application of the semi-additive method, on each surface of the inner wiring substrate 3, an insulating layer 5 is formed. A via hole is formed in the insulating layer 5, for example, by laser processing. On a surface of the insulating layer 5 including an inner surface of the via hole, an electro-less copper plating is implemented. A layer of the electro-less copper plating is formed as a seed layer of plating. By implementing an electrolysis copper plating on the electro-less plating layer including the inside of the via hole, a via 7 and a wiring layer 6 are formed. By repeating multiple times such forming process of the insulating layer 5 and the via 7 depending on the laminate numbers, a plurality of build-up layers 4 are formed.

On an element mounting surface 1a side of the wiring substrate 1 having the build-up layer 4, an electrode pad (C4 pad) 8 which is connected to an inner wiring comprising the wiring layer 6, the via hole 7 and the through hole portion 2 is formed. On the other hand, on an opposite side to the element mounting surface 1a, that is a connection surface 1b side, an exterior connection terminal 9 which is connected to the inner wiring is formed. The electrode pad 8 and the exterior connection terminal 9 are electrically connected through the inner wiring comprising the wiring layer 6, the via 7, and the through hole portion 2. A metal bump such as a solder bump, an Au bump and the like is applied to the exterior connection terminal 9.

The element mounting surface 1a side of the wiring substrate 1 has a power source region X corresponding to a center portion of element and a signal wiring region Y corresponding to a peripheral portion of element. In the power source region X of a build-up layer 4, a stacked via 10 for a power source system is formed. The stacked via 10 is formed by stacking vias 7 linearly. Concretely, as shown in FIG. 2, respective vias 10A, 10B, and 10C, which are provided in each of build-up layers 4A, 4B and 4C, are stacked to align in a straight line. Since the stacked via 10 decreases its wiring distance, it is effective to the power source system wiring which is required to decrease its inductance. On the other hand, the signal wiring region Y has vias 7 which is disposed to move its position to effectively treat the signal wiring.

As mentioned above, since the stacked via 10 which constitutes the power source system via is easily subjected to the stress concentration compared with ordinary via, breakdown due to thermal stress and the like when mounting the element or operating the device, are readily occurred. Specially, the via which is disposed directly below the electrode pad 8 at the element mounting surface 1a side, that is, via 10A provided at the build-up layer 4C, which is the third layer positioned at the top layer, is readily subjected to the maximum stress based on the difference of thermal expansion coefficient between the wiring substrate 1 and a mounting element (semiconductor element).

Therefore, in the wiring substrate 1 of this embodiment, as shown in FIG. 2, the diameter D1 of via 10C which is provided at the top build-up layer 4C is made to be larger than the diameter D2 of vias 10A and 10B which are provided at the other two build-up layers 4A and 4B. That is, the via 10C is made to the large diameter via. Here, the shape of via generally has a tapered shape (trapezoidal shape in the cross section) whose diameter of upper side is larger than that of lower supper. Wherein the specified diameter is based on the diameter of the upper side (the same applies hereafter).

By making the diameter D1 of the via 10C, to which the maximum stress is applied, larger than the diameter D2 of the other vias 10A and 10B (D1>D2), the stress concentration at the via 10C can be relaxed based on the diameter of via. That is, by making an area of via 10C larger, the stress concentration is relieved. Thus, it becomes possible to suppress the breakdown of stacked via 10 due to thermal stresses and the like when mounting the element or operating. A concrete diameter of the large diameter via (via 10C) can be properly determined depending on the degree of stress concentration, a diameter of signal via and the like.

For example, the diameters of via/via land for signal system is 60/100 μm. When the values are made as standard values, and the diameters of via/via land of via 10A and 10B are made the same as the diameters of the signal system, the diameters of via/via land of the large diameter via 10C, for example are set to be 70/110 μm. When the diameter of via for signal system is in the range of about 50 μm to about 60 μm, the diameter D1 of the large diameter via 10C is preferably 1.2 or more times of the diameter D2 of the other vias 10A and 10B. Namely, it is preferable to satisfy the expression 1.2 D2≦D1. If the diameter D1 of large diameter via 10C is smaller than 1.2 D2, the stress concentration of the stacked via 10 could not be sufficiently relieved. The diameter D1 of large diameter via 10C is preferable to enlarged in a permissible range of substrate design.

As described above, when forming the power source system via with the stacked via 10, by using the large diameter via as the via 10C of the build-up layer 4C of the top layer, the breakdown of stacked via 10 due to the stress concentration can be suppressed. Thereby, it becomes possible to decrease the incidence rate of failure and to improve the reliability. Thus, it becomes possible to provide a wiring substrate 1 having a greatly improved reliability at the time of mounting a semiconductor element. Such wiring substrate 1 is suitable for a package substrate of a semiconductor element.

Here, the via to be a large diameter via is not limited to the via 1C of the build-up layer 4C positioned at the top layer. For example, depending on a structure of build-up layers 4 and an inner wiring substrate 3, there is a case that the maximum stress is applied to a via 10A of a build-up layer 4A positioned at a first layer which is the lowest layer. That is, due to the difference of thermal expansion coefficient between a Cu wiring provided on a surface of the inner wiring substrate 3 and an insulating resin layer 5 constituting the build-up layer 4, and further the numbers of build up layers 4, there is a case that the maximum stress is applied to the via 10A provided in the build-up layer 4A which is the lowest layer. In this case, it is preferable to make the via 10A in the build-up layer 4A which is the lowest layer to the large diameter via.

It is preferable that the large diameter via is applied to a via of a build-up layer that the maximum stress is added. The large diameter via is not limited to the via 10C of the build-up layer 4C which is at the top layer or the via 10A of the build-up layer 4A which is at the lowest layer. In a case that the maximum stress is applied to a via of a build-up layer other than the above vias, the via for target may be a large diameter via. In the stacked via 10 which is a power source system, when only the via that maximum stress is added is made to be the large diameter via, the other vias can be processed with the same condition as a signal system via. Accordingly, the cost up (an increase of processing cost due to the change of via diameter), which is necessary to process the large diameter via, can be suppressed.

Next, we will describe a wiring substrate according to a second embodiment, with referring to FIG. 3. FIG. 3 is a cross sectional view showing an essential part of the wiring substrate of the second embodiment. The wiring substrate 20 of the second embodiment has the same overall structure as that of the first embodiment, and basically has the same overall structure of the wiring substrate 1 as that shown in FIG. 1. Further, the same parts as those of FIGS. 1 and 2 have the same reference numbers, and the description thereof is partly omitted.

Similar to the first embodiment, a wiring substrate 20 according to the second embodiment has a build-up layer 4 having three layers in which on a main surface of an inner wiring substrate 3 (element mounting surface) a first build-up layer 4A, a second build-up layer 4B and a third build-up layer 4C are formed in turn. An illustration of a connection surface side of the inner wiring substrate 3 is omitted. However, a build-up layer having three layers is laminated similar with the element mounting face.

The element mounting surface 20a side of the wiring substrate 20 has a power source region x corresponding to an element center portion and a signal wiring region Y corresponding to an element peripheral portion. The power source region X has a stacked via 21 as a power source system wiring. In the stacked via 21, via 21A, via 21B and via 21C, which are respectively provided in build up layers 4A, 4B, and 4C, are stacked in such that respective vias are aligned to form a straight line.

In the signal wiring region Y, signal system vias (vias constituting the signal wiring) 22 are disposed by displacing their positions to form a wiring. The signal wiring region Y is requested to pass a signal wiring between electrode pads 8 in order to take out the signal bump positioned in an inside portion of the element to an outside thereof. When many line numbers for disposing the signal bump are requested, in order to prevent a cost up accompanying the increase of numbers of the build-up layer, the numbers of signal wiring which passes through between electrode pads 8 increase depending on the increased line numbers. Due to the above, the miniaturization of signal system via 22 (including via land) is requested together with the miniaturization of the signal wiring.

On the other hand, in the power source region X corresponding to the element central portion, different from the case of signal wiring region Y described above, it is not necessary to draw out a wiring. Consequently, comparing with the signal wiring region Y, the diameter of via/via land can be larger. Therefore, a stacked via 21 which causes stress concentration has a structure that large diameter vias having a diameter larger than other vias in same build-up layer 4 are stacked. That is, respective vias 21A, 21B, and 21C which constitute the stacked via 21 for the power source system have diameter D1 larger than diameter D3 of signal system via 22 in same build-up layer 4. The stacked via 21 is constituted with such large diameter vias.

The diameter D1 of respective vias 21A, 21B and 21C constituting the stacked via 21 which produces the stress concentration is to be larger than the diameter D3 of the other vias in the same layer, that is, the diameter D3 of vias of the signal system (D3<D1), thereby the stress concentration to the stacked via 21 being relaxed based on the via diameter (via area). Accordingly, at the time of mounting the element and operating the device, the breakdown of the stacked via 21 due to the thermal stress and the like can be suppressed. Concrete diameter of the large diameter via (via 21A, 21B and 21C) constituting the stacked via 21 can be set depending on the degree of stress concentration and the diameter of the signal system via 22.

For example, when a diameter of via/via land in the signal system via 22 is 60/100 μm, the diameter of via/via land of a large diameter via (via 21A, 21B, and 21C) is set to be 70/110 μm. When the diameter of signal system via 22 is in the range of about 50 μm to about 60 μm, the diameter D1 of the large diameter vias 21A, 21B, and 21C is preferably 1.2 or more times of the diameter D3 of the signal system via 22. Namely, it is preferable to satisfy the expression 1.2 D3≦D1. If the diameter D1 of large diameter vias 21A, 21B, and 21C is smaller than 1.2 D3, the stress concentration of the stacked via 21 could not be sufficiently relieved. The diameter D1 of large diameter vias 21A, 21B, and 21C is preferable to enlarged in a permissible range of substrate design.

As described above, when applying a stacked via 21 as a power source system via, by forming a stacked via 21 with large diameter vias 21A, 21B and 21C which can relief the stress concentration, the breakdown of the stacked via 21 can be suppressed. By constituting the whole stacked via 21 with the large diameter vias 21A, 21B and 21C, resistance to stress can further improved. Furthermore, an inductance in the power source system can be more decreased. Thereby, it becomes possible to decrease the incidence rate of failure in the wiring substrate, and to improve the reliability thereof. Namely, it is possible to provide a wiring substrate 20 whose reliability at the time of mounting the element is widely enhanced. The wiring substrate 20 is suitable for a package of semiconductor element.

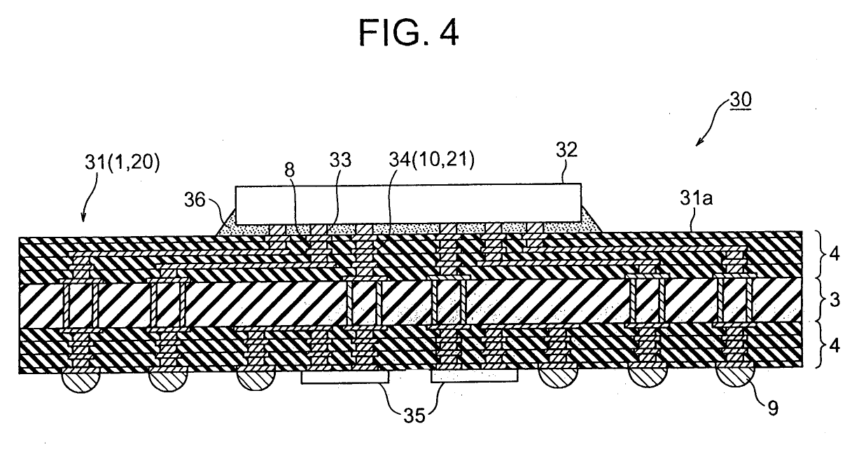

Next, we will describe a semiconductor device according to an embodiment of the present invention with reference to FIG. 4. FIG. 4 is a cross sectional view showing a structure of a semiconductor device according to an embodiment of the invention. The semiconductor device 30 shown in FIG. 4 comprises the wiring substrate 1 according to the first embodiment or the wiring substrate 20 according to the second embodiment as a package substrate 31. On an element mounting surface 31a of the package substrate 31, a semiconductor element 32 is connected in a flip-chip method. The semiconductor device (semiconductor package) 30 is constituted by the package substrate 31 and the semiconductor element 32.

The package substrate 31 and the semiconductor element 32 are electrically and mechanically connected with metal bumps 33 which are disposed between the electrode pads 8 of the package substrate 31 (1, 20) and terminals of the semiconductor element 32 that the illustration is omitted. A power source terminal of the semiconductor element 32 is connected to a chip condenser 35 through a power source system wiring having a stacked via 34 (10, 21). The power source terminal of the semiconductor element 32 is connected to a power source device through the chip condenser 35. Between the package substrate 31 and the semiconductor element 32, an under-fill resin 36 is filled and cured.

The semiconductor device 30 according to the embodiment mentioned above applies the stacked via 34 (10, 21) in the power source system wiring of the package substrate 31, hence the inductance of the power source system can be effectively decreased. In addition, the breakdown of the stacked via 34 in the power source system due to a thermal stress at the time of mounting the semiconductor element or actual operating the device is suppressed. Thereby, it becomes possible to decrease of the incidence rate of failure and to improve the reliability. That is, it is possible to provide a semiconductor device 30 of which the decrease of switching noise due to the lowering of inductance in the power source system wiring can be obtained and further the reliability to the thermal stress and the like is widely improved.

The present invention is not limited to the above embodiments, and can apply to various wiring substrate having a stacked via and various semiconductor device on which a semiconductor element is mounted. Such a wiring substrate and a semiconductor device are also included in the present invention. In a scope which does not deviate from the sprit of the invention, it is possible to be transformed in various forms. Further, by combining the embodiments of the invention as possible as, it is possible to obtain a combined effect. Further, the above embodiments include various stages of the invention. Therefore it is possible to extract various inventions by suitable combinations of plural structural requirements.

What is claimed is:

1. A wiring substrate, comprising:
an inner wiring substrate having through hole portions; and
a plurality of build up layers formed by laminating on at least one main surface of the inner wiring substrate and each having vias electrically connected to the through hole portions,
wherein the plurality of build up layers have a stacked via which is formed by stacking the vias in multiple steps to form a straight line, and the stacked via has a large diameter via whose diameter is larger than other via forming the stacked via.

2. A wiring substrate according to claim 1, wherein the stacked via constitutes a power source system wiring.

3. A wiring substrate according to claim 1, wherein the large diameter via is disposed on a top layer or a bottom layer in the plurality of build up layers disposed on an element mounting side.

4. A wiring substrate according to claim 1, wherein the large diameter via has the diameter satisfying an expression of 1.2 D2≦D1, which D1 is a diameter of the large diameter via, and D2 is a diameter of the other via.

5. A wiring substrate, comprising:
an inner wiring substrate having through hole portions; and
a plurality of build up layers formed by laminating on at least one main surface of the inner wiring substrate and each having vias electrically connected to the through hole portions,
wherein the plurality of build up layers have a stacked via which is formed by stacking the vias in multiple steps to form a straight line, and the stacked via is constituted with large diameter vias, the large diameter via having a diameter larger than other via formed in the same build up layer.

6. A wiring substrate according to claim 5, wherein the stacked via constitutes a power source system wiring.

7. A wiring substrate according to claim 6, wherein the large diameter via constituting the power source system wiring has the diameter larger than the other via constituting a signal system wiring.

8. A wiring substrate according to claim 5, wherein the large diameter via has the diameter satisfying an expression of 1.2 D3≦D1, which D1 is a diameter of the large diameter via, and D3 is a diameter of the other via.

9. A semiconductor device, comprising:
a wiring substrate comprising an inner wiring substrate having through hole portions and a plurality of build up layers formed by laminating on at least one main surface of the inner wiring substrate and each having vias electrically connected to the through hole portions; and
a semiconductor element mounted on the build up layers and electrically connected to the via,
wherein the plurality of build up layers have a stacked via which is formed by stacking the vias in multiple steps to form a straight line, and the stacked via has a large diameter via whose diameter is larger than other via forming the stacked via.

10. A semiconductor device according to claim 9, wherein the stacked via constitutes a power source system wiring, and is electrically connected to a power source terminal of the semiconductor element.

11. A semiconductor device, comprising:
a wiring substrate comprising an inner wiring substrate having through hole portions and a plurality of build up layers formed by laminating on at least one main surface of the inner wiring substrate and each having vias electrically connected to the through hole portions; and
a semiconductor element mounted on the build up layers and electrically connected to the via,
wherein the plurality of build up layers have a stacked via which is formed by stacking the vias in multiple steps to form a straight line, and the stacked via is constituted of large diameter vias, the large diameter via having a diameter larger than other via formed in the same build up layer.

12. A semiconductor device according to claim 11, wherein the stacked via constitutes a power source wiring, and is electrically connected to a power source terminal of the semiconductor element.
